(19) United States
(12) Patent Application Publication
(10) Pub. No.: US 2025/0318248 A1
(43) Pub. Date: Oct. 9, 2025

(54) DEEP VIA STRUCTURES FOR STACKED TRANSISTOR DEVICES

(71) Applicant: International Business Machines Corporation, Armonk, NY (US)

(72) Inventors: Ruilong Xie, Niskayuna, NY (US); Joshua M. Rubin, Albany, NY (US); Qianwen Chen, Chappaqua, NY (US); Tao Li, Slingerlands, NY (US); Lawrence Alfred Clevenger, Saratoga Springs, NY (US); Albert M. Chu, Nashua, NH (US); Nicholas Anthony Lanzillo, Wynantskill, NY (US); Brent A. Anderson, Jericho, VT (US); David Wolpert, Poughkeepsie, NY (US)

(21) Appl. No.: 18/626,674

(22) Filed: Apr. 4, 2024

(51) Int. Cl. H01L 21/8238; H01L 23/522; H01L 23/528; H01L 23/532; H01L 27/092; H01L 29/06; H01L 29/423; H01L 29/786

(52) U.S. Cl. CPC H10D 84/038; H01L 23/5226; H01L 23/5286; H01L 23/53266; H10D 30/6735; H10D 30/6757; H10D 62/118; H10D 84/0186; H10D 84/85

(57) ABSTRACT

A semiconductor device comprises a plurality of first transistors, a plurality of second transistors stacked on the plurality of first transistors, and a first dielectric layer and a second dielectric layer between the plurality of first transistors and the plurality of second transistors. The second dielectric layer is stacked on the first dielectric layer. The semiconductor device also comprises an interconnect layer between the first dielectric layer and the second dielectric layer, a first interconnect wiring level on a first side of a stacked structure comprising the plurality of second transistors stacked on the plurality of first transistors, and a second interconnect wiring level on a second side of the stacked structure opposite the first side. A via is electrically connected to and disposed between the first and second interconnect wiring levels, wherein the via is further electrically connected to the interconnect layer.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments of the invention provide structures for and techniques for forming deep vias for stacked transistor devices.

In one embodiment, a semiconductor device includes a plurality of first transistors, a plurality of second transistors stacked on the plurality of first transistors, and a first dielectric layer and a second dielectric layer between the plurality of first transistors and the plurality of second transistors. The second dielectric layer is stacked on the first dielectric layer. The semiconductor device also includes an interconnect layer between the first dielectric layer and the second dielectric layer, a first interconnect wiring level on a first side of a stacked structure including the plurality of second transistors stacked on the plurality of first transistors, and a second interconnect wiring level on a second side of the stacked structure opposite the first side. A via is electrically connected to and disposed between the first and second interconnect wiring levels, wherein the via is further electrically connected to the interconnect layer.

In another embodiment, a semiconductor device includes a first device layer, a second device layer stacked on the first device layer, a bonding dielectric layer between the first device layer and the second device layer, and an additional dielectric layer between the first device layer and the second device layer, wherein the additional dielectric layer is stacked on the bonding dielectric layer. The semiconductor device further includes an interconnect layer between the bonding dielectric layer and the additional dielectric layer, a first interconnect wiring level on a first side of a stacked structure including the second device layer stacked on the first device layer, a second interconnect wiring level on a second side of the stacked structure opposite the first side, and a via electrically connected to and disposed between the first and second interconnect wiring levels. The via is further electrically connected to the interconnect layer.

In another embodiment, a semiconductor device includes a first device layer, a second device layer stacked on the first device layer, and a first dielectric layer and a second dielectric layer between the first device layer and the second device layer, wherein the second dielectric layer is stacked on the first dielectric layer. The semiconductor device further includes an extension layer between the first dielectric layer and the second dielectric layer, wherein the first dielectric layer contacts at least two surfaces of the extension layer. A first interconnect wiring level is on a first side of a stacked structure including the second device layer stacked on the first device layer, and a second interconnect wiring level is on a second side of the stacked structure opposite the first side. A via is electrically connected to and disposed between the first and second interconnect wiring levels, wherein the via contacts the extension layer.

These and other features and advantages of embodiments described herein will become more apparent from the accompanying drawings and the following detailed description.

### BRIEF DESCRIPTION OF THE DRAWINGS

FIG. 1A depicts a top view of a semiconductor structure with lines X and Y on which the cross-sectional views of FIGS. 1B, 1C and 5A-9B are based, according to an embodiment of the invention.

FIG. 1B depicts a first cross-sectional view corresponding to the line X in FIG. 1A and illustrating a lower level of a stacked transistor configuration with a bonding dielectric deposited thereon, according to an embodiment of the invention.

FIG. 1C depicts a second cross-sectional view corresponding to the line Y in FIG. 1A and illustrating a lower level of a stacked transistor configuration with a bonding dielectric deposited thereon, according to an embodiment of the invention.

FIG. 2 depicts a cross-sectional view of a portion of a semiconductor structure including nanosheet stack and a dielectric layer formed on a carrier wafer, according to an embodiment of the invention.

FIG. 3 depicts a cross-sectional view of the portion of the semiconductor structure from FIG. 2 following interconnect formation, according to an embodiment of the invention.

FIG. 4 depicts a cross-sectional view of the portion of the semiconductor structure from FIG. 3 following bonding dielectric formation, according to an embodiment of the invention.

FIG. 5A depicts a first cross-sectional view corresponding to the line X in FIG. 1A and illustrating bonding of the portion of the semiconductor structure from FIG. 4 to the semiconductor structure of FIG. 1A and removal of the carrier wafer, according to an embodiment of the invention.

FIG. 5B depicts a second cross-sectional view corresponding to the line Y in FIG. 1A and illustrating bonding of the portion of the semiconductor structure from FIG. 4 to the semiconductor structure of FIG. 1B and removal of the carrier wafer, according to an embodiment of the invention.

FIG. 6A depicts a first cross-sectional view corresponding to the line X in FIG. 1A and illustrating formation of an upper level of a stacked transistor configuration and middle-of-line (MOL) contact formation, according to an embodiment of the invention.

FIG. 6B depicts a second cross-sectional view corresponding to the line Y in FIG. 1A and illustrating formation of an upper level of a stacked transistor configuration and MOL contact formation, according to an embodiment of the invention.

FIG. 7A depicts a first cross-sectional view corresponding to the line X in FIG. 1A and illustrating formation of frontside back-end-of-line (BEOL) interconnects and backside BEOL interconnects, according to an embodiment of the invention.

FIG. 7B depicts a second cross-sectional view corresponding to the line Y in FIG. 1A and illustrating formation of frontside BEOL interconnects and backside BEOL interconnects, according to an embodiment of the invention.

FIG. 8A depicts a first cross-sectional view corresponding to the line X in FIG. 1A and illustrating formation of frontside BEOL interconnects and backside BEOL interconnects for a semiconductor structure with an alternative deep via configuration, according to an embodiment of the invention.

FIG. 8B depicts a second cross-sectional view corresponding to the line Y in FIG. 1A and illustrating formation of frontside BEOL interconnects and backside BEOL interconnects for a semiconductor structure with an alternative deep via configuration, according to an embodiment of the invention.

FIG. 9A depicts a first cross-sectional view corresponding to the line X in FIG. 1A and illustrating formation of frontside BEOL interconnects and backside BEOL interconnects for a semiconductor structure with an alternative deep via configuration, according to an embodiment of the invention.

FIG. 9B depicts a second cross-sectional view corresponding to the line Y in FIG. 1A and illustrating formation of frontside BEOL interconnects and backside BEOL interconnects for a semiconductor structure with an alternative deep via configuration, according to an embodiment of the invention.

### DETAILED DESCRIPTION

Illustrative embodiments of the invention may be described herein in the context of illustrative methods for forming deep via structures for stacked transistor devices, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

In one embodiment, a semiconductor device includes a plurality of first transistors, a plurality of second transistors stacked on the plurality of first transistors, and a first dielectric layer and a second dielectric layer between the plurality of first transistors and the plurality of second transistors. The second dielectric layer is stacked on the first dielectric layer. The semiconductor device also includes an interconnect layer between the first dielectric layer and the second dielectric layer, a first interconnect wiring level on a first side of a stacked structure including the plurality of second transistors stacked on the plurality of first transistors, and a second interconnect wiring level on a second side of the stacked structure opposite the first side. A via is electrically connected to and disposed between the first and second interconnect wiring levels, wherein the via is further electrically connected to the interconnect layer.

The interconnect layer may include one of ruthenium, molybdenum and tungsten. The via may contact the interconnect layer at a side surface of the interconnect layer. The via may be electrically connected to the first and second interconnect wiring levels through respective first and second contacts contacting respective opposite surfaces of the via. The via may be disposed through the first and second dielectric layers.

The first side of the stacked structure may be on a frontside of the semiconductor device, and the second side of the stacked structure may be on a backside of the semiconductor device.

An additional via may be disposed between the first interconnect wiring level and the interconnect layer, wherein the additional via is electrically connected to the first interconnect wiring level and to the interconnect layer. A bottom surface of the additional via may contact a top surface of the interconnect layer. The additional via may be disposed through the second dielectric layer.

An additional via may be disposed between the second interconnect wiring level and the interconnect layer, wherein the additional via is electrically connected to the first interconnect wiring level and to the interconnect layer. A top surface of the additional via may contact a bottom surface of the interconnect layer. The additional via may be disposed through the first dielectric layer.

The plurality of first transistors and the plurality of second transistors may respectively be parts of at least a first complementary metal-oxide semiconductor device and a second complementary metal-oxide semiconductor device. The first interconnect wiring level may include at least one of a first power rail and a first plurality of signal wires. The second interconnect wiring level may include at least one of a second power rail and a second plurality of signal wires.

Advantageously, illustrative embodiments provide structures for and methods of forming deep vias for stacked transistor devices to connect frontside interconnect wiring levels with backside interconnect wiring levels. A stacked device architecture (e.g., stacked complementary metal-oxide-semiconductor (CMOS) architecture) uses vias and a local interconnect layer to connect wires of a frontside interconnect wiring level with wires of a backside interconnect wiring level so that input signals (e.g., gate input signals) and power voltages can be transmitted between a frontside interconnect wiring level and a backside interconnect wiring level.

In another embodiment, a semiconductor device includes a first device layer, a second device layer stacked on the first device layer, a bonding dielectric layer between the first device layer and the second device layer, and an additional dielectric layer between the first device layer and the second device layer, wherein the additional dielectric layer is stacked on the bonding dielectric layer. The semiconductor device further includes an interconnect layer between the bonding dielectric layer and the additional dielectric layer, a first interconnect wiring level on a first side of a stacked structure including the second device layer stacked on the first device layer, a second interconnect wiring level on a second side of the stacked structure opposite the first side, and a via electrically connected to and disposed between the first and second interconnect wiring levels. The via is further electrically connected to the interconnect layer.

The via may contact the interconnect layer at a side surface of the interconnect layer, and the via may be disposed through the bonding and additional dielectric layers. An additional via may be disposed through the additional dielectric layer and between the first interconnect wiring level and the interconnect layer, wherein the additional via is electrically connected to the first interconnect wiring level and to the interconnect layer. An additional via may be disposed through the bonding dielectric layer and between the second interconnect wiring level and the interconnect layer, wherein the additional via is electrically connected to the first interconnect wiring level and to the interconnect layer.

In another embodiment, a semiconductor device includes a first device layer, a second device layer stacked on the first device layer, and a first dielectric layer and a second dielectric layer between the first device layer and the second device layer, wherein the second dielectric layer is stacked on the first dielectric layer. The semiconductor device further includes an extension layer between the first dielectric layer and the second dielectric layer, wherein the first dielectric layer contacts at least two surfaces of the extension layer. A first interconnect wiring level is on a first side of a stacked structure including the second device layer stacked on the first device layer, and a second interconnect wiring level is on a second side of the stacked structure opposite the first side. A via is electrically connected to and disposed between the first and second interconnect wiring levels, wherein the via contacts the extension layer.

The extension layer may include one of ruthenium, tungsten and one or more carbon nanotubes. The via may contact the extension layer at a side surface of the extension layer.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe) between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

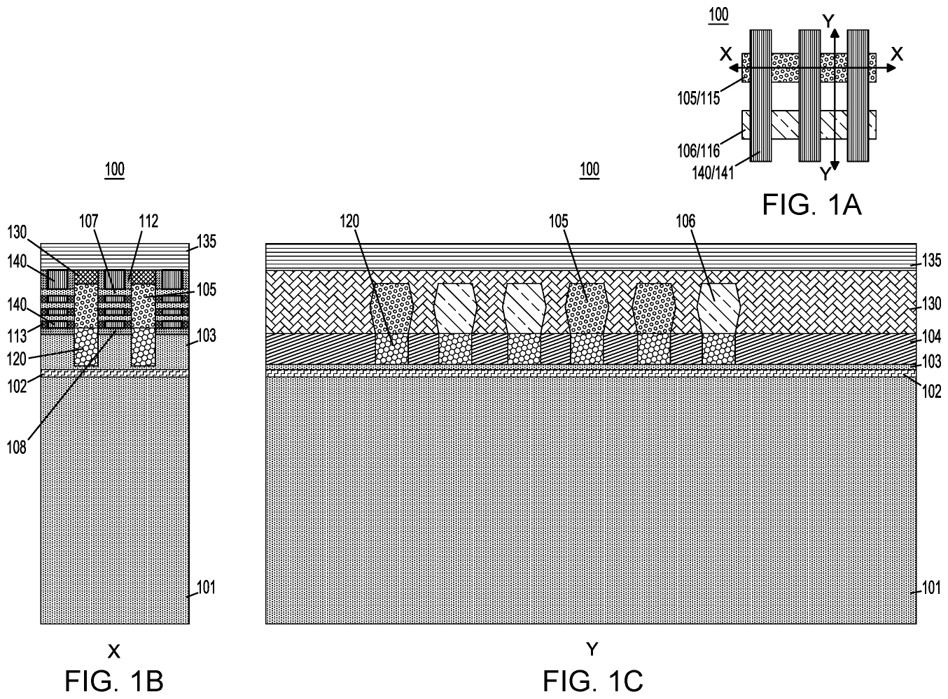

FIGS. 1B and 1C respectively depict first and second cross-sectional views corresponding to the lines X and Y in FIG. 1A and illustrating a lower level of a stacked transistor configuration with a bonding dielectric deposited thereon. As explained in more detail herein, FIG. 1A illustrates gate structures 140/141, n-type source/drain regions 105/115 and p-type source/drain regions 106/116 for lower and upper device levels.

Referring to the cross-sectional views in FIGS. 1B and 1C, a semiconductor structure 100 includes a plurality of lower transistors (also referred to herein as “first transistors”). The lower transistors are part of a lower device layer (also referred to herein as a “first device layer”). In illustrative embodiments, the lower device layer can be a CMOS device layer. The lower transistors include nanosheet transistors. For example, the lower transistors include a plurality of first channel layers 107 alternately stacked with and surrounded by first gate structures 140. The lower transistors further include first n-type source/drain regions 105 and first p-type source/drain regions 106.

A semiconductor substrate 101 and a semiconductor layer 103 include semiconductor material including, but not limited to, silicon, III-V, II-V compound semiconductor materials or other like semiconductor materials. In addition, multiple layers of the semiconductor materials can be used as the semiconductor material of the semiconductor substrate 101 and semiconductor layer 103. An etch stop layer 102 is formed on the semiconductor substrate 101 between the semiconductor substrate 101 and the semiconductor layer 103. In an illustrative embodiment, the etch stop layer 102 includes silicon germanium (SiGe) with, for example, a germanium concentration of about 30% (e.g., SiGe30) or SiO₂ and the semiconductor substrate 101 and semiconductor layer 103 include silicon.

According to one or more embodiments, the etch stop layer 102 is epitaxially grown on the semiconductor substrate 101, and the semiconductor layer 103 is epitaxially grown on the etch stop layer 102. The embodiments are not necessarily limited to the shown number of first channel layers 107, and there may be more or less layers in the same alternating configuration depending on design constraints with the first gate structures 140.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

A bottom dielectric layer 108 (e.g., bottom dielectric isolation (BDI) layer) is disposed between the semiconductor layer 103 and lowermost first gate structures 140 and first n-type source/drain regions 105 and/or first p-type source/drain regions 106. In an illustrative embodiment, the bottom dielectric layer 108 includes a dielectric material such as, for example, SiN, SiBCN, SiOCN, SiCN, SiOC, silicon dioxide (SiO₂).

Isolation regions 104 (e.g., shallow trench isolation (STI)) regions are formed between nanosheet stacks in recessed portions of the semiconductor layer 103. Isolation regions 104 including dielectric material fill in the recessed portions of the semiconductor layer 103. The dielectric material may include, for example, SiO2, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

In the semiconductor structure 100, first gate spacers 112 are disposed on sides of the uppermost first gate structures 140. The spacer material can include for example, one or more dielectrics, including, but not necessarily limited to, SiN, SiON, SiOC, SiCN, BN, SiBN, SiBCN, SiOCN, SiOx, and combinations thereof. The first gate spacers 112 can be formed by any suitable technique such as deposition followed by directional etching. Deposition may include, but is not limited to, ALD or CVD. Directional etching may include but is not limited to, reactive ion etching (RIE).

First inner spacers 113 are disposed on sides of lower first gate structures 140 above and/or under end portions of the first channel layers 107. The material of the first inner spacers 113 can include, but is not necessarily limited to, a nitride, such as, SiN, SiON, SiCN, BN, SiBN, SiBCN or SiOCN. In an illustrative embodiment, the first gate spacers 112 are formed from the same or similar material to that of the first inner spacers 113. Like the first gate spacers 112, the first inner spacers 113 can be formed by any suitable techniques such as deposition followed by isotropic etching.

Prior to formation of the first n-type source/drain regions 105 and first p-type source/drain regions 106, portions of the semiconductor layer 103 are removed, such that portions of the semiconductor layer 103 are recessed to create openings (e.g., “trenches”) in the semiconductor layer 103. Sacrificial placeholder layers 120 for backside source/drain contacts are formed in the trenches. In more detail, the trenches are filled with sacrificial placeholder layers 120 including, for example, SiGe, III-V semiconductor material or other semiconductor material. The sacrificial placeholder layers 120 are deposited in the trenches using deposition techniques such as, for example, epitaxial growth, CVD, PECVD, RFCVD, PVD, ALD, MBD, PLD, and/or LSMCD.

First n-type source/drain regions 105 and first p-type source/drain regions 106 are epitaxially grown between the nanosheet stacks corresponding to the lower transistors. The first n-type source/drain regions 105 and first p-type source/drain regions 106 correspond to lower transistors formed by first channel layers 107 and first gate structures 140. The first n-type source/drain regions 105 and first p-type source/drain regions 106 include epitaxial layers grown from sides of first channel layers 107 and/or from top surfaces of the sacrificial placeholder layers 120. As can be seen, the first n-type source/drain regions 105 and first p-type source/drain regions 106 are formed on and contact corresponding ones of underlying sacrificial placeholder layers 120.

Side surfaces of respective ones of the first channel layers 107 contact a side surface of at least one adjacent first n-type source/drain region 105 or first p-type source/drain region 106.

According to a non-limiting embodiment of the present invention, the conditions of the epitaxial growth process for the first n-type source/drain regions 105 and first p-type source/drain regions 106 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the first n-type source/drain regions 105 can include silicon doped regions with n-type dopants including, for example, phosphorus (P), arsenic (As) and antimony (Sb). In the case of p-type FETS (pFETs), the first p-type source/drain regions 106 can include silicon doped regions with p-type dopants including, for example, boron (B), boron fluoride (BF2), gallium (Ga), indium (In), and thallium (TI).

A first inter-layer dielectric (ILD) layer 130 is deposited to fill in portions on and around the first n-type source/drain regions 105 and first p-type source/drain regions 106. The first ILD layer 130 is deposited using deposition techniques such as, for example, CVD, PECVD, RFCVD, PVD, ALD, MBD, PLD, and/or LSMCD, followed by a planarization process, such as, chemical mechanical planarization (CMP) to planarize the first ILD layer 130. The first ILD layer 130 may include, for example, SiO₂, SiOC, SiOCN or some other dielectric.

In illustrative embodiments, each of the first gate structures 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the first gate structures 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

A first bonding dielectric layer 135 is deposited on the first ILD layer 130 and on the lower transistors including the first gate structures 140 and first gate spacers 112. The first bonding dielectric layer 135 is deposited using deposition techniques such as, for example, CVD, PECVD, RFCVD, PVD, ALD, MBD, PLD, and/or LSMCD, followed by a planarization process, such as, CMP to planarize the first bonding dielectric layer 135. The first bonding dielectric layer 135 may include, for example, an oxide such as SiO₂, SiN, AlN, or some other dielectric.

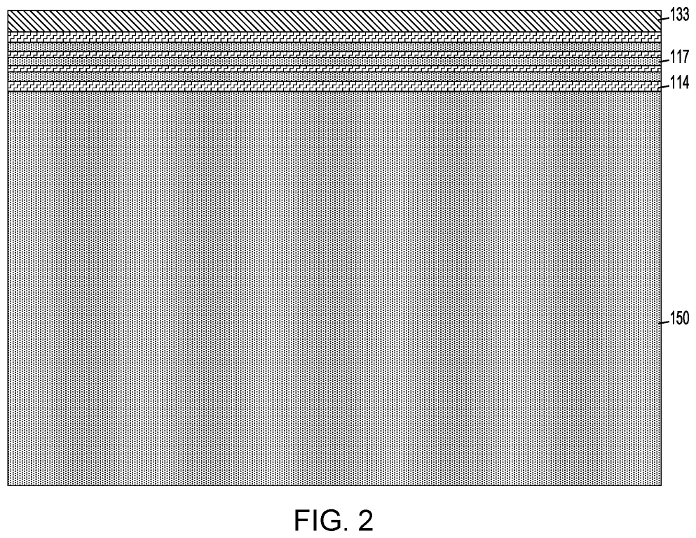

Referring to the cross-sectional view in FIG. 2, a portion to be added to the semiconductor structure 100 includes a nanosheet stack and a dielectric layer 133 formed on a carrier wafer 150. The nanosheet stack includes a plurality of sacrificial layers 114 and a plurality of second channel layers 117.

In an illustrative embodiment, the sacrificial layers 114 include SiGe and the second channel layers 117 include silicon. In illustrative embodiments, the sacrificial layers 114 include a germanium concentration of about 25% (e.g., SiGe25), but the embodiments are not necessarily limited to SiGe25 for the sacrificial layers 114. Like the semiconductor substrate 101, the carrier wafer 150 includes semiconductor material including, but not limited to, silicon (Si), III-V, II-V compound semiconductor materials or other like semiconductor materials.

The sacrificial layers 114 and second channel layers 117 are epitaxially grown in an alternating and stacked configuration on the carrier wafer 150. A first sacrificial layer 114 is followed by a first one of the second channel layers 117 on the first sacrificial layer 114, which is followed by a second sacrificial layer 114 on the first one of the second channel layers 117, and so on. As can be understood, the sacrificial layers 114 and second channel layers 117 are epitaxially grown from their corresponding underlying semiconductor layers.

While four sacrificial layers 114 and three second channel layers 117 are shown, the embodiments of the present invention are not necessarily limited to the shown number of sacrificial layers 114 and second channel layers 117, and there may be more or less layers in the same alternating configuration depending on design constraints. The sacrificial layers 114, as described further herein, are eventually removed and replaced by gate structures.

Although SiGe is described as a sacrificial material for sacrificial layers 114, other materials can be used as long as the sacrificial layers 114 have the property of being able to be removed selectively compared to the material of the second channel layers 117.

The dielectric layer 133 is deposited on the nanosheet using, for example, CVD or another one of the deposition techniques noted herein. In illustrative embodiments, a material of the dielectric layer can be SiO₂, SiN, SiCN, or another dielectric material. A vertical thickness of the dielectric layer 133 can be in the range of about 20 nm to about 2 μm.

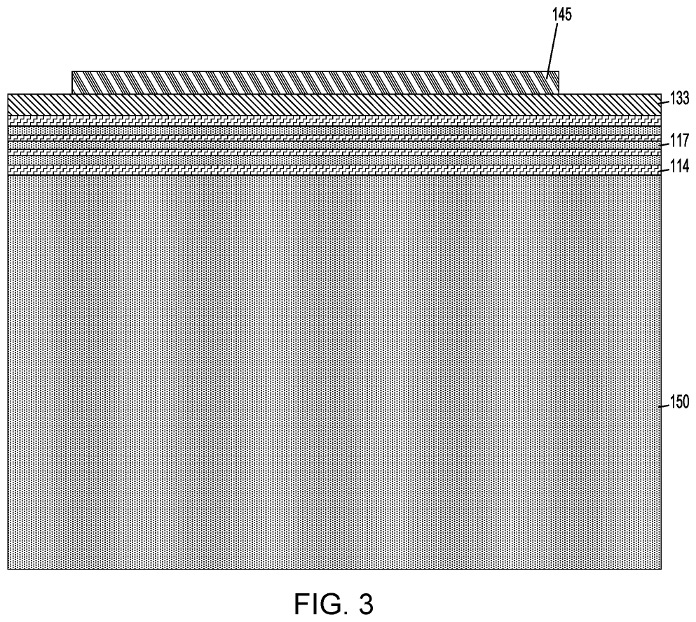

Referring to FIG. 3, a local interconnect layer 145 is deposited on a portion of the dielectric layer 133. The local interconnect layer 145 is deposited using deposition techniques such as, for example, CVD, PECVD, RFCVD, PVD, ALD, MBD, PLD, LSMCD, sputtering and/or plating followed by a planarization process, such as, CMP to planarize the local interconnect layer 145. The local interconnect layer 145 may include, for example, material which forms a line with high electrical conductivity or a line with high electrical conductivity and high thermal conductivity. For example, in illustrative embodiments, the local interconnect layer includes ruthenium (Ru), molybdenum (Mo) or tungsten (W).

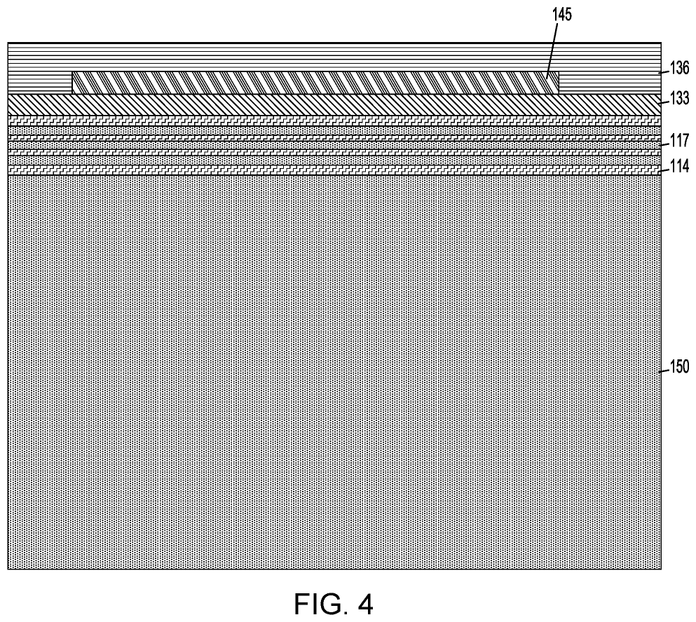

Referring to FIG. 4, a second bonding dielectric layer 136 is deposited on the FIG. 3 structure. As can be seen, the second bonding dielectric layer 136 is deposited on the dielectric layer 133 and on and around the local interconnect layer 145. The second bonding dielectric layer 136 is formed on a top surface and wraps around side surfaces of the local interconnect layer 145. Other portions of the second bonding dielectric layer 136 are formed on a top surface of the dielectric layer 133. Similar to the first bonding dielectric layer 135, the second bonding dielectric layer 136 is deposited using deposition techniques such as, for example, CVD, PECVD, RFCVD, PVD, ALD, MBD, PLD, and/or LSMCD, followed by a planarization process, such as, CMP to planarize the second bonding dielectric layer 136. The second bonding dielectric layer 136 may include, for example, an oxide such as SiO₂, SiN, AlN, or some other dielectric.

In an illustrative embodiment, the second bonding dielectric layer 136 includes multiple dielectric layers. For example, a first dielectric layer of the second bonding dielectric layer 136 is deposited to cover the local interconnect layer 145, followed by a CMP process. Then, a second dielectric layer of the second bonding dielectric layer 136 is deposited on the first dielectric layer of the second bonding dielectric layer 136 and on the local interconnect layer 145, followed by a planarization process such as CMP to form a bonding interface to interface with the first bonding dielectric layer 135. The material of the second dielectric layer of the second bonding dielectric layer 136 can be the same as or different from the material of the first dielectric layer of the second bonding dielectric layer 136. The first dielectric layer of the second bonding dielectric layer 136 is thick enough to completely cover the local interconnect layer 145. Post CMP, the second dielectric layer of the second bonding dielectric layer 136 may be thinner or thicker than the first dielectric layer of the second bonding dielectric layer 136.

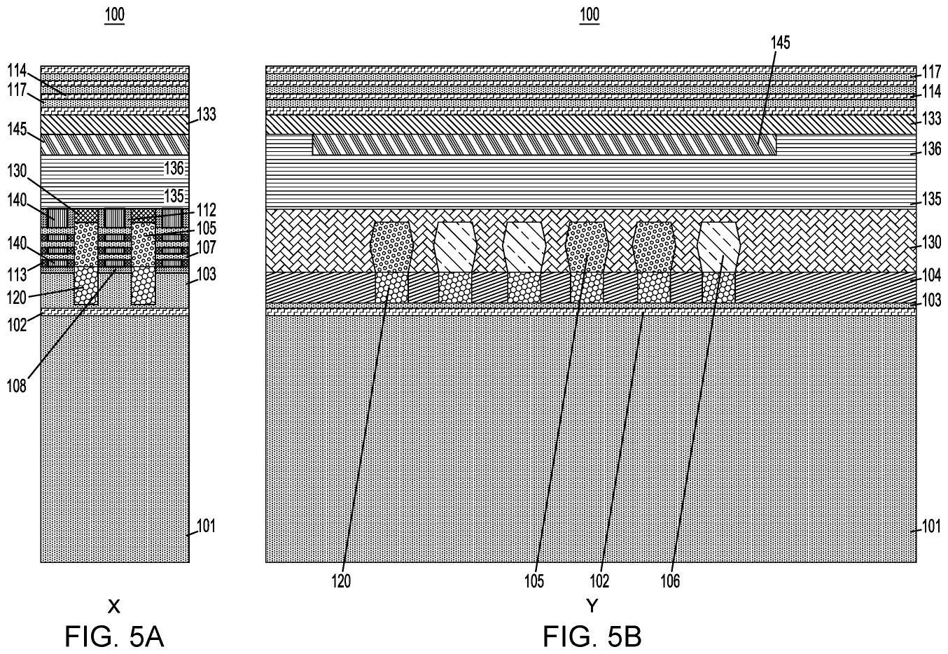

Referring to FIGS. 5A and 5B, the structure from FIG. 4 is flipped (e.g., rotated 180 degrees), bonded to the semiconductor structure 100 from FIGS. 1A and 1B, and the carrier wafer 150 is removed. The removal process to remove the carrier wafer 150 includes etching of the carrier wafer 150, which stops at an exposed one of the sacrificial layers 114 (the top sacrificial layer in FIGS. 5A and 5B). The carrier wafer 150 is selectively etched with an etchant that selectively etches silicon with respect to a material of the sacrificial layers 114 (e.g., SiGe).

A bonding process to bond the second bonding dielectric layer 136 to the first bonding dielectric layer 135 includes fusion or direct wafer bonding processes.

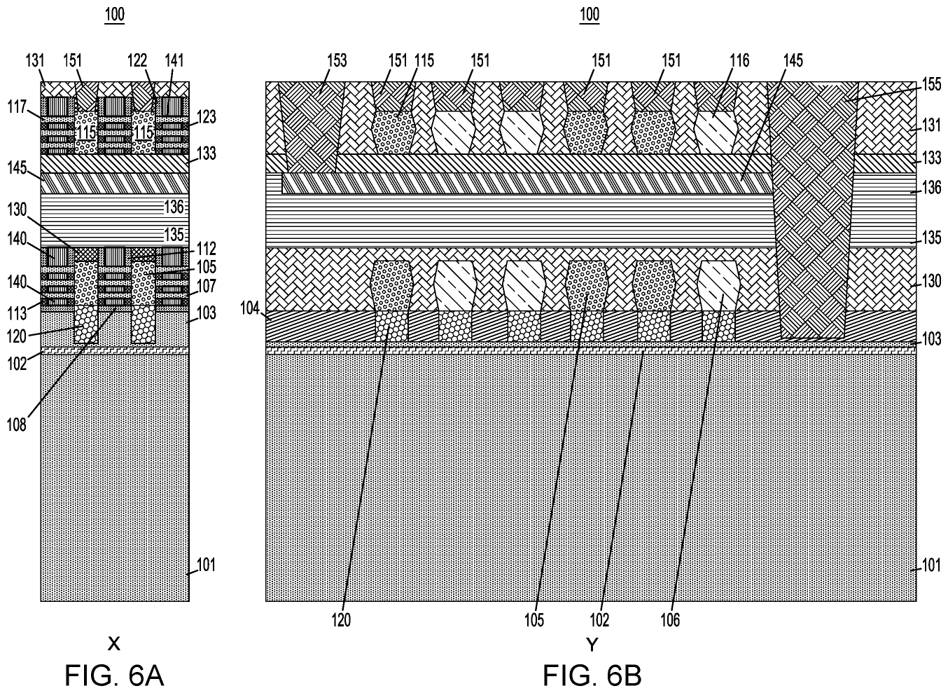

Referring to FIGS. 6A and 6B, an upper device level of a stacked transistor configuration and MOL contacts are formed. The nanosheet stack including the sacrificial layers 114 and the second channel layers 117 are patterned to remove portions of the nanosheet stack down to the dielectric layer 133. Similar to the formation of the lower device layer, the sacrificial layers 114 are replaced with second gate structures 141 and a plurality of upper transistors (also referred to herein as “second transistors”) to form an upper device layer (also referred to herein as a “second device layer”). In illustrative embodiments, the upper device layer can be a CMOS device layer. The upper transistors include nanosheet transistors. For example, the upper transistors include the plurality of second channel layers 117 alternately stacked with and surrounded by second gate structures 141. The upper transistors further include second n-type source/drain regions 115 and second p-type source/drain regions 116.

Second gate spacers 122 are disposed on sides of the uppermost second gate structures 141. The second gate spacers 122 can include the same or similar materials as those of the first gate spacers 112, and may be formed using the same or similar techniques as those used for the first gate spacers 112. Like the first inner spacers 113, second inner spacers 123 are disposed on sides of lower second gate structures 141 above and/or under end portions of the second channel layers 117. The second inner spacers 123 can include the same or similar materials as those of the first inner spacers 113, and may be formed using the same or similar techniques as those used for the first inner spacers 113.

Second n-type source/drain regions 115 and second p-type source/drain regions 116 are epitaxially grown between the nanosheet stacks corresponding to the upper transistors. The second n-type source/drain regions 115 and second p-type source/drain regions 116 correspond to upper transistors formed by second channel layers 117 and second gate structures 141. The second n-type source/drain regions 115 and second p-type source/drain regions 116 include epitaxial layers grown from sides of second channel layers 117. As can be seen, the second n-type source/drain regions 115 and second p-type source/drain regions 116 are formed on and contact the dielectric layer 133. Side surfaces of respective ones of the second channel layers 117 contact a side surface of at least one adjacent second n-type source/drain region 115 or second p-type source/drain region 116.

According to a non-limiting embodiment of the present invention, the conditions of the epitaxial growth process for the second n-type source/drain regions 115 and second p-type source/drain regions 116 are the same as or similar to the epitaxial growth process conditions for the first n-type source/drain regions 105 and first p-type source/drain regions 106. The second n-type source/drain regions 115 can include silicon doped with n-type dopants including, for example, phosphorus (P), arsenic (As) and antimony (Sb). The second p-type source/drain regions 116 can include silicon doped with p-type dopants including, for example, boron (B), boron fluoride (BF₂), gallium (Ga), indium (In), and thallium (TI).

A second ILD layer 131 is deposited to fill in portions on and around the second n-type source/drain regions 115 and second p-type source/drain regions 116. The second ILD layer 131 is deposited using deposition techniques such as, for example, CVD, PECVD, RFCVD, PVD, ALD, MBD, PLD, and/or LSMCD, followed by a planarization process, such as, CMP to planarize the second ILD layer 131. The second ILD layer 131 may include, for example, SiO₂, SiOC, SiOCN or some other dielectric.

In illustrative embodiments, each of the second gate structures 141 includes the same or similar materials and layers (e.g., high-K dielectric layer, WFM layer and/or gate metal layer) as those of the first gate structures 140. As can be seen in FIGS. 6A and 6B, the semiconductor structure 100 includes a stacked structure of the plurality of upper transistors (also referred to herein as “second transistors”) stacked on the plurality of lower transistors (also referred to herein as “first transistors”). The lower transistors are part of a lower device layer (also referred to herein as a “first device layer”) and the upper transistors are part of an upper device layer (also referred to herein as a “second device layer”). In illustrative embodiments, the upper and lower device layers can be CMOS device layers.

As used herein, “frontside or “first side” refers to a side on top of the semiconductor layer 103 and/or in front of, on top of or in an upward direction from the stacked structure of the upper nanosheet transistors stacked on the lower nanosheet transistors in the orientation shown in the cross-sectional figures. As used herein, “backside” or “second side” refers to a side below the semiconductor layer 103 and/or behind, under, below or in a downward direction from the stacked structure of the upper nanosheet transistors stacked on the lower nanosheet transistors in the orientation shown in the cross-sectional figures (e.g., opposite the “frontside”). In other words, frontside wiring is above or on top of the stacked structure of the upper device layer (e.g., upper nanosheet transistors) stacked on the lower device layer (e.g., lower nanosheet transistors) in the orientation shown in the cross-sectional figures, and backside wiring is below or under the stacked structure of the upper device layer (e.g., upper nanosheet transistors) stacked on the lower device layer (e.g., lower nanosheet transistors) in the orientation shown in the cross-sectional figures.

Using masks, openings are formed by removing exposed portions of the second ILD layer 131 where MOL contacts and vias are to be formed. The openings are formed by, for example, an etch process to remove the exposed portions of the second ILD layer 131 not covered by masks. Referring to FIGS. 6A and 6B, conductive material is deposited on the second n-type source/drain regions 115 and second p-type source/drain regions 116 in openings formed by the removal of the exposed portions of the second ILD layer 131 to form frontside source/drain contacts 151, which land on and contact respective second n-type source/drain regions 115 or second p-type source/drain regions 116.

In addition, a portion of the second ILD layer 131 not covered by a mask and an underlying portion of the dielectric layer 133 are removed to form an opening exposing a top surface of the local interconnect layer 145. Referring to FIGS. 6A and 6B, conductive material is deposited on the top surface of the local interconnect layer 145 in the opening to form a frontside via 153, which lands on and contacts a portion of the top surface of the local interconnect layer 145. The frontside via 153 is formed through the second ILD layer 131 and through the dielectric layer 133 that is disposed on top of the local interconnect layer 145.

Another portion of the second ILD layer 131 not covered by a mask, and underlying portions of the dielectric layer 133, of the first and second bonding dielectric layers 135 and 136, of the first ILD layer 130 and of an isolation region 104 are removed to form an opening exposing a side surface of the local interconnect layer 145. Referring to FIGS. 6A and 6B, conductive material is deposited in the opening to form a deep via 155, which contacts the exposed side surface (right side surface in FIG. 6B) of the local interconnect layer 145. The deep via 155 is formed through the second ILD layer 131, the dielectric layer 133, the first and second bonding dielectric layers 135 and 136, the first ILD layer 130 and at least part of the isolation region 104. The deep via 155 extends from a frontside of the semiconductor structure 100 to a backside of the semiconductor structure 100.

The conductive materials of the frontside source/drain contacts 151, frontside via 153 and deep via 155 includes, for example, metal layers. The metal layers include, for example, a silicide layer, such as Ni, Ti, NiPt, etc., a metal adhesion layer, such as TiN, and a conductive metal fill layer, such as W, Al, Co, Ru, Cu, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the second ILD layer 131. In some embodiments, the silicide layer and/or metal adhesion layer can be omitted.

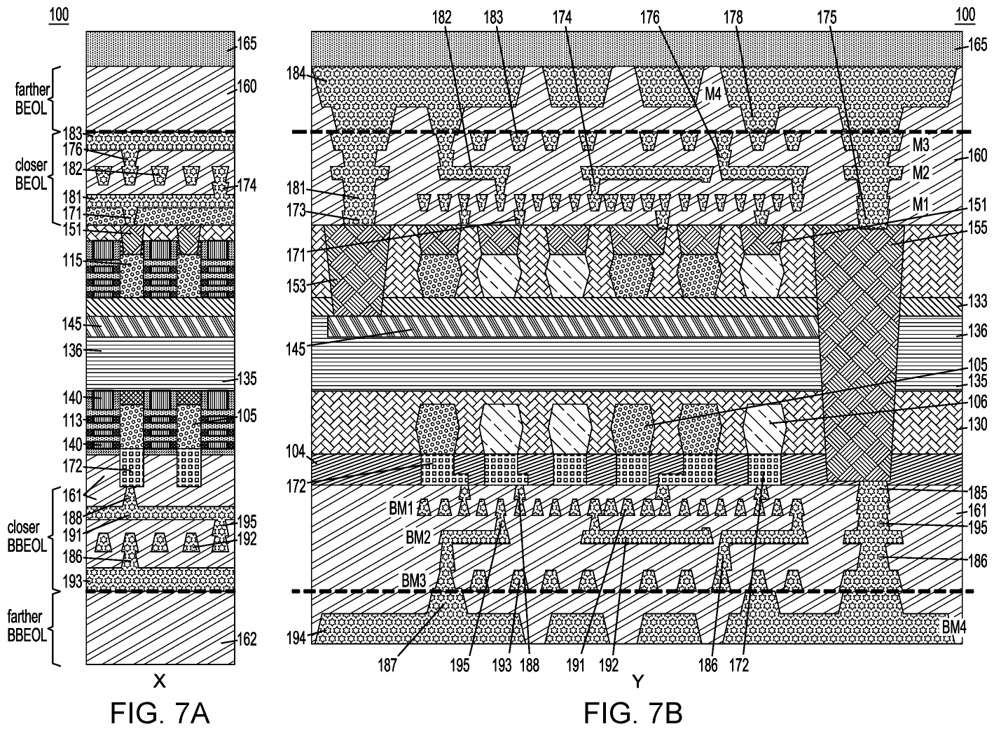

Referring to FIGS. 7A and 7B, backside source/drain contacts, frontside BEOL interconnects and backside BEOL interconnects are formed in the semiconductor structure 100. In more detail, a frontside ILD layer 160 is formed over the first ILD layer 130 including the frontside source/drain contacts 151, frontside via 153 and deep via 155 formed therein. The frontside ILD layer 160 is deposited using deposition techniques such as, for example, CVD, PECVD, RFCVD, PVD, ALD, MBD, PLD, and/or LSMCD, followed by a planarization process, such as, CMP to planarize the frontside ILD layer 160. The frontside ILD layer 160 may include, for example, SiO₂, SiOC, SiOCN or some other dielectric.

In the illustrative embodiment shown in FIGS. 7A an 7B, multiple frontside interconnect wiring levels M1, M2, M3 and M4 respectively including a plurality of first, second, third and fourth frontside interconnects 181, 182, 183 and 184 are formed in the frontside ILD layer 160. Vias 171 formed in the frontside ILD layer 160 connect some of the first frontside interconnects 181 to the frontside source/drain contacts 151. A via 175 connects one of the first frontside interconnects 181 to the deep via 155, and a via 173 connects another one of the first frontside interconnects 181 to the frontside via 153. Respective vias 174 connect respective second frontside interconnects 182 with respective first frontside interconnects 181. Respective vias 176 connect respective third frontside interconnects 183 with respective second frontside interconnects 182. Respective vias 178 connect respective fourth frontside interconnects 184 with respective third frontside interconnects 183. A dotted line above the third frontside interconnect wiring level M3 indicates where closer BEOL and farther BEOL regions are located and that there could be multiple layers which are not shown between the closer BEOL and farther BEOL regions. Closer and farther respectively indicating closer to and farther from the stacked structure of upper and lower device layers.

The material of the plurality of first, second, third and fourth frontside interconnects 181, 182, 183 and 184, and of the vias 171, 173, 174, 175, 176 and 178 includes for example, metal layers. The metal layers include, for example, a silicide layer, such as Ni, Ti, NiPt, etc., a metal adhesion layer, such as TiN, and a conductive metal fill layer, such as W, Al, Co, Ru, Cu, etc., and can be deposited using, for example, a deposition technique such as CVD, PECVD, RFCVD, PVD, ALD, MBD, PLD, LSMCD, sputtering and/or plating, followed by a planarization process such as, CMP. In some embodiments, the silicide layer and/or metal adhesion layer can be omitted.

A carrier wafer 165 is formed on the frontside ILD layer 160 following formation of the frontside BEOL interconnects. The carrier wafer 165 may be formed of materials similar to that of the semiconductor substrate 101 and semiconductor layer 103, and may be formed over the frontside BEOL interconnects using a wafer bonding process, such as dielectric-to-dielectric bonding. Using the carrier wafer 165, the semiconductor structure 100 may be “flipped” (e.g., rotated 180 degrees) so that the structure is inverted. In addition, the semiconductor substrate 101 is removed from the backside of the semiconductor structure 100. The removal process, which includes etching of the semiconductor substrate 101, stops at the etch stop layer 102. For example, the semiconductor substrate 101 is selectively etched with an etchant that selectively etches silicon with respect to a material of the etch stop layer 102 (e.g., SiGe).

The etch stop layer 102 and the semiconductor layer 103 (e.g., silicon layer) are selectively removed from the semiconductor structure 100 with respect to the sacrificial placeholder layers 120 and the isolation regions 104. The etch stop layer 102 is removed, followed by removal of the semiconductor layer 103, wherein portions of the isolation regions 104 and the sacrificial placeholder layers 120 are exposed. Etching processes for removal of the etch stop layer 102 include, for example, IBE by Ar/CHF₃ based chemistry.

A backside ILD layer 161 is deposited to fill in areas formerly occupied by the semiconductor layer 103. The backside ILD layer 161 is deposited using deposition techniques such as, for example, CVD, PECVD, RFCVD, PVD, ALD, MBD, PLD, and/or LSMCD, followed by a planarization process, such as, CMP to remove excess portions of the backside ILD layer 161 deposited on top of the sacrificial placeholder layers 120 so that the backside ILD layer 161 is coplanar with surfaces of the sacrificial placeholder layers 120. The surfaces of the sacrificial placeholder layers 120 are exposed following the CMP process. The backside ILD layer 161 may include, for example, SiOx, SiOC, SiOCN or some other dielectric.

The sacrificial placeholder layers 120 are selectively removed to create openings exposing backside portions of the first n-type source/drain regions 105 and first p-type source/drain regions 106. The sacrificial placeholder layers 120 are removed using, for example, a selective dry or wet etch process. Backside source/drain contacts 172 are formed in the backside ILD layer 161 in the openings left by the removal of the sacrificial placeholder layers 120. Metal layers are deposited in the openings to form the backside source/drain contacts 172. The metal layers include, for example, a silicide layer, such as Ni, Ti, NiPt, etc., a metal adhesion layer, such as TiN, and a conductive metal fill layer, such as W, Al, Co, Ru, Cu, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 161. In some embodiments, the silicide layer and/or metal adhesion layer can be omitted.

The backside source/drain contacts 172 contact respective backsides of the first n-type source/drain regions 105 and first p-type source/drain regions 106 in the lower device level. The backside source/drain contacts 172 extend through the backside ILD layer 161 and on sides of the isolation regions 104 to land on and contact the backsides of the corresponding first n-type source/drain regions 105 and first p-type source/drain regions 106.

Additional backside ILD material is deposited to increase the thickness of the backside ILD layer 161. Multiple backside interconnect wiring levels BM1, BM2, BM3 and BM4 respectively including a plurality of first, second, third and fourth backside interconnects 191, 192, 193 and 194 are formed in the backside ILD layer 161. Vias 188 formed in the backside ILD layer 161 connect some of the first backside interconnects 191 to the backside source/drain contacts 172. A via 185 connects one of the first backside interconnects 191 to the deep via 155. Respective vias 195 connect respective second backside interconnects 192 with respective first backside interconnects 191. Respective vias 186 connect respective third backside interconnects 193 with respective second backside interconnects 192. Respective vias 187 connect respective fourth backside interconnects 194 with respective third backside interconnects 193. A dotted line under the third backside interconnect wiring level BM3 indicates where closer backside BEOL (BBEOL) and farther BBEOL regions are located and that there could be multiple layers which are not shown between the closer BBEOL and farther BBEOL regions. Closer and farther respectively indicating closer to and farther from the stacked structure of upper and lower device layers.

The material of the plurality of first, second, third and fourth backside interconnects 191, 192, 193 and 194, and of the vias 195, 185, 186, 187 and 188 includes for example, metal layers. The metal layers include, for example, a silicide layer, such as Ni, Ti, NiPt, etc., a metal adhesion layer, such as TiN, and a conductive metal fill layer, such as W, Al, Co, Ru, Cu, etc., and can be deposited using, for example, a deposition technique such as CVD, PECVD, RFCVD, PVD, ALD, MBD, PLD, LSMCD, sputtering and/or plating, followed by a planarization process such as, CMP. In some embodiments, the silicide layer and/or metal adhesion layer can be omitted.

As can be understood from FIG. 7B, the vias 175 and 185 contact respective upper and lower surfaces of the deep via 155, and electrically connect the deep via 155 to at least a first frontside interconnect 181 of the first frontside interconnect wiring level M1, and to at least a first backside interconnect 191 of the first backside interconnect wiring level BM1. The deep via 155 is further electrically connected to the second, third and fourth frontside interconnect wiring levels M2, M3 and M4 through a combination of vias 174, 176 and 178 and second, third and fourth frontside interconnects 182, 183 and 184. The deep via 155 is further electrically connected to the second, third and fourth backside interconnect wiring levels BM2, BM3 and BM4 through a combination of vias 195, 186 and 187, and second, third and fourth backside interconnects 192, 193 and 194. As can be seen, a side surface of the deep via 155 contacts a side surface of the local interconnect layer 145, and, by virtue of the contact, is electrically connected to the local interconnect layer 145. The frontside via 153 contacts a top surface of the local interconnect layer 145 and is electrically connected to the local interconnect layer 145 by virtue of the contact. The deep via 155 and the frontside via 153 are electrically connected to each other through the local interconnect layer 145.

As can be understood from FIG. 7B, the via 173 and the top surface of the local interconnect layer 145 contact respective lower and upper surfaces of the frontside via 153. The frontside via 153 is electrically connected to at least a first frontside interconnect 181 of the first frontside interconnect wiring level M1 through the via 173. The frontside via 153 is further electrically connected to the second, third and fourth frontside interconnect wiring levels M2, M3 and M4 through a combination of vias 174, 176 and 178 and second, third and fourth frontside interconnects 182, 183 and 184. One or more of the first, second, third and fourth frontside interconnects 181, 182, 183 and 184 and of the first, second, third and fourth backside interconnects 191, 192, 193 and 194 includes a power rail and/or signal wires.

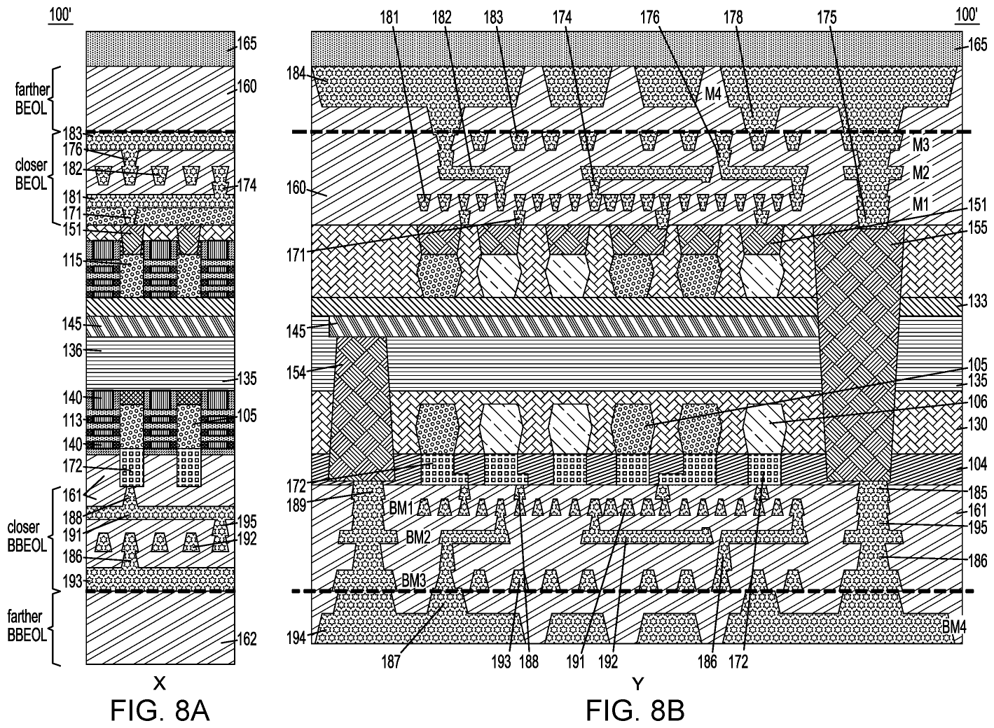

FIGS. 8A and 8B illustrate formation of frontside and backside source/drain contacts and frontside and backside BEOL interconnects for a semiconductor structure 100′ with an alternative deep via configuration. The same reference numbers as those in FIGS. 7A and 7B represent the same or similar elements in FIGS. 8A and 8B, and for the sake of brevity, repetitive descriptions are omitted. Unlike the semiconductor structure 100, the semiconductor structure 100′ does not include the frontside via 153, and includes a backside via 154. Like the semiconductor structure 100, the semiconductor structure 100′ includes the deep via 155 contacting and electrically connected to the local interconnect layer 145. The backside via 154 is formed through the isolation regions 104, the first ILD layer 130 and the first and second bonding dielectric layers 135 and 136. The backside via 154 contacts a portion of the bottom surface of the local interconnect layer 145 and is electrically connected to the local interconnect layer 145. As a result of being electrically connected to the local interconnect layer 145, the backside via 154 is electrically connected to the deep via 155.

The backside via 154 is electrically connected to at least a first backside interconnect 191 of the first backside interconnect wiring level BM1 through a via 189. The via 189 contacts a bottom surface of the backside via 154. The backside via 154 is further electrically connected to the second, third and fourth backside interconnect wiring levels BM2, BM3 and BM4 through a combination of vias 195, 186 and 187, and second, third and fourth backside interconnects 192, 193 and 194. The material of the backside via 154 and of the via 189 includes, for example, metal layers. The metal layers include, for example, a silicide layer, such as Ni, Ti, NiPt, etc., a metal adhesion layer, such as TiN, and a conductive metal fill layer, such as W, Al, Co, Ru, Cu, etc., and can be deposited using, for example, a deposition technique such as CVD, PECVD, RFCVD, PVD, ALD, MBD, PLD, LSMCD, sputtering and/or plating, followed by a planarization process such as, CMP. In some embodiments, the silicide layer and/or metal adhesion layer can be omitted.

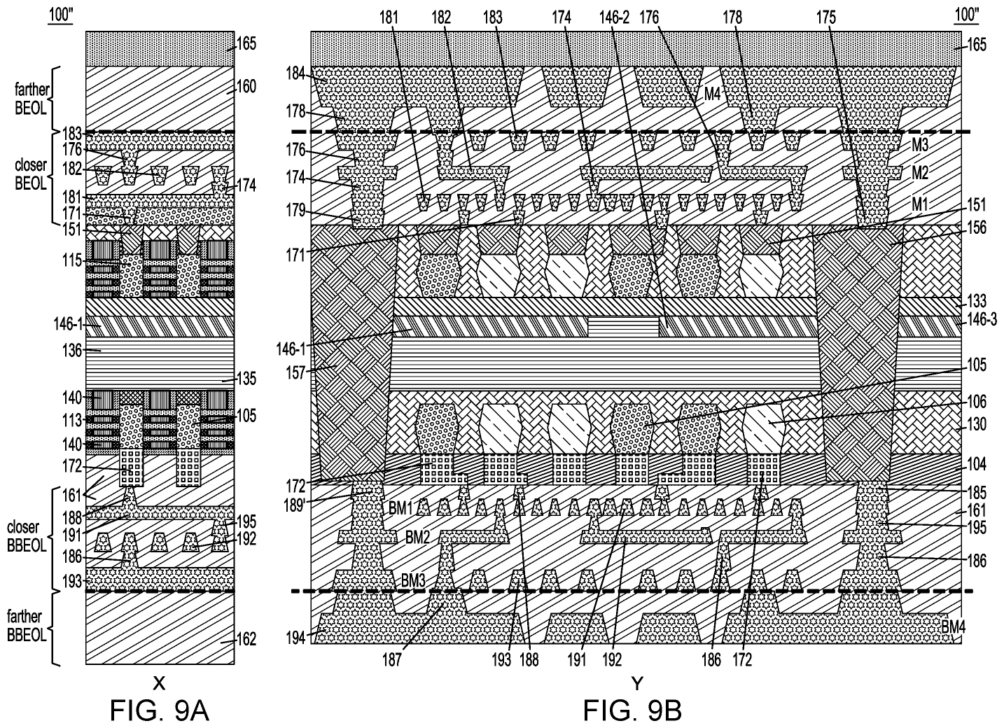

FIGS. 9A and 9B illustrate formation of frontside and backside source/drain contacts and frontside and backside BEOL interconnects for a semiconductor structure 100″ with another alternative deep via configuration. The same reference numbers as those in FIGS. 7A, 7B, 8A and 8B represent the same or similar elements in FIGS. 9A and 9B, and for the sake of brevity, repetitive descriptions are omitted. Unlike the semiconductor structures 100 and 100′, the semiconductor structure 100″ includes first, second and third extension layers 146-1, 146-2 and 146-3 for thermal dissipation instead of the local interconnect layer 145. The first, second and third extension layers 146-1, 146-2 and 146-3 do not function as interconnects. In illustrative embodiments, the first, second and third extension layers 146-1, 146-2 and 146-3 include metal with high thermal stability such as, for example, ruthenium or tungsten, or carbon nanotubes. Similar to the local interconnect layer 145, the first, second and third extension layers 146-1, 146-2 and 146-3 are formed in the second bonding dielectric layer 136 between the first bonding dielectric layer 135 and the dielectric layer 133. The first and second extension layers 146-1 and 146-2 are contacted by the second bonding dielectric layer 136 on bottom and side surfaces and by the dielectric layer 133 on top surfaces thereof. The first and second extension layers 146-1 and 146-2 are isolated from each other by a portion of the second bonding dielectric layer 136 between the first and second extension layers 146-1 and 146-2.

The semiconductor structure 100″ includes a first deep via 156. The first deep via 156 is similar to the deep via 155, except that left and right side surfaces of the first deep via 156 respectively contact side surfaces of the second and third extension layers 146-2 and 146-3. Like the deep via 155, the first deep via 156 is formed through the second ILD layer 131, the dielectric layer 133, the first and second bonding dielectric layers 135 and 136, the first ILD layer 130 and at least part of the isolation region 104. The first deep via 156 extends from a frontside of the semiconductor structure 100″ to a backside of the semiconductor structure 100″. A via 175 connects one of the first frontside interconnects 181 to the first deep via 156. The vias 175 and 185 contact respective upper and lower surfaces of the first deep via 156, and electrically connect the first deep via 156 to at least a first frontside interconnect 181 of the first frontside interconnect wiring level M1, and to at least a first backside interconnect 191 of the first backside interconnect wiring level BM1. The first deep via 156 is further electrically connected to the second, third and fourth frontside interconnect wiring levels M2, M3 and M4 through a combination of vias 174, 176 and 178 and second, third and fourth frontside interconnects 182, 183 and 184. The first deep via 156 is further electrically connected to the second, third and fourth backside interconnect wiring levels BM2, BM3 and BM4 through a combination of vias 195, 186 and 187, and second, third and fourth backside interconnects 192, 193 and 194. As can be seen, opposite side surfaces of the first deep via 156 contacts side surfaces of respective second and third extension layers 146-2 and 146-3. The second and third extension layers 146-2 and 146-3 dissipate heat from the first deep via 156.

The semiconductor structure 100″ incudes a second deep via 157. The second deep via 157 is similar to the first deep via 156. The second deep via 157 is formed through the second ILD layer 131, the dielectric layer 133, the first and second bonding dielectric layers 135 and 136, the first ILD layer 130 and at least part of the isolation region 104. The second deep via 157 extends from a frontside of the semiconductor structure 100″ to a backside of the semiconductor structure 100″. A via 179 connects one of the first frontside interconnects 181 to the second deep via 157. The vias 179 and 189′ contact respective upper and lower surfaces of the second deep via 157, and electrically connect the second deep via 157 to at least a first frontside interconnect 181 of the first frontside interconnect wiring level M1, and to at least a first backside interconnect 191 of the first backside interconnect wiring level BM1. The second deep via 157 is further electrically connected to the second, third and fourth frontside interconnect wiring levels M2, M3 and M4 through a combination of vias 174, 176 and 178 and second, third and fourth frontside interconnects 182, 183 and 184. The second deep via 157 is further electrically connected to the second, third and fourth backside interconnect wiring levels BM2, BM3 and BM4 through a combination of vias 195, 186 and 187, and second, third and fourth backside interconnects 192, 193 and 194. As can be seen, a side surface of the second deep via 157 contacts a side surface of the first extension layer 146-1. The first extension layer 146-1 dissipates heat from the second deep via 157 and is isolated from the second and third extension layers 146-2 and 146-3.

The material of the first and second deep vias 156 and 157 and of the via 189′ includes for example, metal layers. The metal layers include, for example, a silicide layer, such as Ni, Ti, NiPt, etc., a metal adhesion layer, such as TiN, and a conductive metal fill layer, such as W, Al, Co, Ru, Cu, etc., and can be deposited using, for example, a deposition technique such as CVD, PECVD, RFCVD, PVD, ALD, MBD, PLD, LSMCD, sputtering and/or plating, followed by a planarization process such as, CMP. In some embodiments, the silicide layer and/or metal adhesion layer can be omitted.

The frontside interconnect wiring levels M1-M4 and backside interconnect wiring levels BM1-BM4 may include various power delivery network (PDN) structures such as, but not necessarily limited to, interconnects in a power supply path from voltage regulator modules (VRMs) to circuits. The interconnects can include, for example, power and ground planes in circuit boards, cables, connectors and capacitors associated with a power supply.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the illustrative embodiments provide structures for and techniques for forming deep vias and local interconnect layers or extension layers to connect frontside interconnect wiring levels with backside interconnect wiring levels, while also dissipating heat. For example, illustrative embodiments permit the formation of high thermal budget interconnects to be disposed in a bonding dielectric layer between upper and lower CMOS device layers. The bonding dielectric layers increase thermal dissipation.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a plurality of first transistors;
a plurality of second transistors stacked on the plurality of first transistors;
a first dielectric layer between the plurality of first transistors and the plurality of second transistors;
a second dielectric layer between the plurality of first transistors and the plurality of second transistors, wherein the second dielectric layer is stacked on the first dielectric layer;
an interconnect layer between the first dielectric layer and the second dielectric layer;
a first interconnect wiring level on a first side of a stacked structure comprising the plurality of second transistors stacked on the plurality of first transistors;
a second interconnect wiring level on a second side of the stacked structure opposite the first side; and
a via electrically connected to and disposed between the first and second interconnect wiring levels, wherein the via is further electrically connected to the interconnect layer.

2. The semiconductor device of claim 1, wherein the interconnect layer comprises one of ruthenium, molybdenum and tungsten.

3. The semiconductor device of claim 1, wherein the via contacts the interconnect layer at a side surface of the interconnect layer.

4. The semiconductor device of claim 1, wherein the via is electrically connected to the first and second interconnect wiring levels through respective first and second contacts contacting respective opposite surfaces of the via.

5. The semiconductor device of claim 1, wherein the first side of the stacked structure is on a frontside of the semiconductor device, and the second side of the stacked structure is on a backside of the semiconductor device.

6. The semiconductor device of claim 1, wherein the via is disposed through the first and second dielectric layers.

7. The semiconductor device of claim 1, further comprising an additional via disposed between the first interconnect wiring level and the interconnect layer, wherein the additional via is electrically connected to the first interconnect wiring level and to the interconnect layer.

8. The semiconductor device of claim 7, wherein a bottom surface of the additional via contacts a top surface of the interconnect layer.

9. The semiconductor device of claim 7, wherein the additional via is disposed through the second dielectric layer.

10. The semiconductor device of claim 1, further comprising an additional via disposed between the second interconnect wiring level and the interconnect layer, wherein the additional via is electrically connected to the first interconnect wiring level and to the interconnect layer.

11. The semiconductor device of claim 10, wherein a top surface of the additional via contacts a bottom surface of the interconnect layer.

12. The semiconductor device of claim 10, wherein the additional via is disposed through the first dielectric layer.

13. The semiconductor device of claim 1, wherein:
the plurality of first transistors and the plurality of second transistors are respectively parts of at least a first complementary metal-oxide semiconductor device and a second complementary metal-oxide semiconductor device;
the first interconnect wiring level comprises at least one of a first power rail and a first plurality of signal wires; and
the second interconnect wiring level comprises at least one of a second power rail and a second plurality of signal wires.

14. A semiconductor device comprising:
a first device layer;
a second device layer stacked on the first device layer;
a bonding dielectric layer between the first device layer and the second device layer;
an additional dielectric layer between the first device layer and the second device layer, wherein the additional dielectric layer is stacked on the bonding dielectric layer;
an interconnect layer between the bonding dielectric layer and the additional dielectric layer;
a first interconnect wiring level on a first side of a stacked structure comprising the second device layer stacked on the first device layer;
a second interconnect wiring level on a second side of the stacked structure opposite the first side; and
a via electrically connected to and disposed between the first and second interconnect wiring levels, wherein the via is further electrically connected to the interconnect layer.

15. The semiconductor device of claim 14, wherein:
the via contacts the interconnect layer at a side surface of the interconnect layer; and
the via is disposed through the bonding and additional dielectric layers.

16. The semiconductor device of claim 14, further comprising an additional via disposed through the additional dielectric layer and between the first interconnect wiring level and the interconnect layer, wherein the additional via is electrically connected to the first interconnect wiring level and to the interconnect layer.

17. The semiconductor device of claim 14, further comprising an additional via disposed through the bonding dielectric layer and between the second interconnect wiring level and the interconnect layer, wherein the additional via is electrically connected to the first interconnect wiring level and to the interconnect layer.

18. A semiconductor device comprising:
a first device layer;
a second device layer stacked on the first device layer;
a first dielectric layer between the first device layer and the second device layer;
a second dielectric layer between the first device layer and the second device layer, wherein the second dielectric layer is stacked on the first dielectric layer;
an extension layer between the first dielectric layer and the second dielectric layer, wherein the first dielectric layer contacts at least two surfaces of the extension layer;
a first interconnect wiring level on a first side of a stacked structure comprising the second device layer stacked on the first device layer;
a second interconnect wiring level on a second side of the stacked structure opposite the first side; and
a via electrically connected to and disposed between the first and second interconnect wiring levels, wherein the via contacts the extension layer.

19. The semiconductor device of claim 18, wherein the extension layer comprises one of ruthenium, tungsten and one or more carbon nanotubes.

20. The semiconductor device of claim 18, wherein the via contacts the extension layer at a side surface of the extension layer.
